(19) United States
(12) Patent Application Publication
(10) Pub. No.: US 2026/0221198 A1
(43) Pub. Date: Jul. 30, 2026

(54) METHODS AND SYSTEMS TO BOOST BIT LINE VOLTAGE BIASING

(71) Applicant: Micron Technology, Inc., Boise, ID (US)

(72) Inventors: Jisuk Kim, San Jose, CA (US); Taehyun Kim, San Jose, CA (US); Dong kyo Shim, Milpitas, CA (US)

(73) Assignee: Micron Technology, Inc., Boise, ID (US)

(21) Appl. No.: 19/449,267

(22) Filed: Jan. 14, 2026

Related U.S. Application Data
(60) Provisional application No. 63/749,976, filed on Jan. 27, 2025.

(51) Int. Cl. G11C 16/24; G11C 16/04; G11C 16/10; G11C 16/26

(52) U.S. Cl. CPC G11C 16/24; G11C 16/0483; G11C 16/10; G11C 16/26

(57) ABSTRACT

Methods, systems, and devices for techniques for boosting bit line voltage biasing. A memory device includes bit lines and controller. The controller, during a program operation of strings of memory cells, identifies, based on a characteristic corresponding to the bit lines, first and second bit line groups. The controller, during the program operation, causes the first bit line group to receive a voltage at a first voltage level. The controller, during the program operation, causes the first bit line group to transition to a floating state such that the first bit line group is electrically isolated. The controller, during the program operation, causes the second bit line group to receive the voltage at the first voltage level. The first and second bit line groups are capacitively coupled such that the voltage level of the first bit line group is boosted from the first voltage level to a second voltage level.

### CROSS-REFERENCE TO RELATED APPLICATIONS

This application claims priority to U.S. Provisional Application No. 63/749,976, filed on January 27, 2025, entitled “METHODS AND SYSTEMS TO BOOST BIT LINE VOLTAGE BIASING,” the content of which is incorporated by reference in its entirety for all purposes.

### TECHNICAL FIELD

This disclosure relates to one or more systems for memory, including techniques for boosting bit line voltage biasing.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 2D illustrates an example of a memory device including multiple blocks of memory cells in accordance with examples as disclosed herein.

FIG. 3A and 3B illustrate an example three-dimensional structure of a memory device in accordance with examples as disclosed herein.

FIG. 4 illustrates a graphical representation of an example select transistor threshold voltage distribution and a relationship between various voltage ranges for the inhibit voltage or a select transistor bias gate voltage.

FIG. 5 illustrates a graphical representation of a bit line set (BLSET) portion of a program loop.

FIGS. 6A and FIG. 6B illustrate different example arrangements of the page buffer of FIG. 1 during the first BLSET phase and the second BLSET phase.

FIG. 7 illustrates a flowchart showing a method that supports techniques for boosting bit line voltage biasing in accordance with examples as disclosed herein.

### DETAILED DESCRIPTION

A memory device includes a memory array formed by multiple pages of memory cells. The memory device programs (e.g., writes data to) the different pages using program operations with each program operation including multiple program loops. During each program loop, the memory device programs different sets of memory cells within a corresponding page. To prevent the memory cells that are already programmed or are not to be programmed from being overwritten during a program loop, the memory device applies an inhibit voltage to the drains of the corresponding memory cells via bit lines of the memory array.

An efficiency of inhibiting memory cells (e.g., the inhibit efficiency of the memory device) can be impacted by relationships between the inhibit voltage, a bias voltage applied to gates of select gate drain (SGD) transistors of the memory array (referred to herein as the SGD gate voltage), and threshold voltage (Vt) distributions of the SGD transistors (referred to herein as the SGD Vt distributions). These factors impact the inhibit efficiency of the memory device because a difference between a level of the SGD gate voltage and the level of the inhibit voltage needs to be lower than or equal to the corresponding SGD Vt distribution to inhibit a corresponding memory cell. For example, if the SGD gate voltage of an SGD transistor is equal to four volts; the inhibit voltage is equal to two volts; and the SGD Vt distribution of the SGD transistor is equal to 2.4 V, the SGD transistor is turned off and the corresponding memory cell is inhibited due to two volts (e.g., the difference between four volts and two volts) being less than 2.4 V (e.g., the SGD Vt distribution).

Some memory devices use a supply voltage (e.g., a Vcc voltage) of the memory devices as the inhibit voltage. In addition to using the supply voltage as the inhibit voltage, these memory devices use the supply voltage to power various components within the memory devices. Some of these memory devices reduce the level of the supply voltage to reduce an overall power consumption of these memory devices. For example, these memory devices can reduce the level of the supply voltage to 1.6V or 1.2V instead of two volts, which will reduce the overall power consumption of these memory devices.

A lower level of the supply voltage increases the difference between the level of the SGD gate voltage and the level of the inhibit voltage, which may prevent the corresponding memory cells from being inhibited. For example, for the same SGD transistor discussed above, if the inhibit voltage is reduced to 1.2 volts, the SGD transistor is turned on and the corresponding memory cell is not inhibited due to 2.8 V (e.g., the difference between four volts and 1.2 V) being greater than 2.4 V (e.g., the SGD Vt distribution). Therefore, while these memory devices reduce overall power consumption, they can also reduce the inhibit efficiency of the memory devices. Reducing the inhibit efficiency can cause the memory devices to operate incorrectly by creating errors in data being written to the memory array.

The present disclosure provides techniques for avoiding or reducing the technical difficulties described above. Some embodiments described in the present disclosure include a memory device that boosts the level of the inhibit voltage on at least a portion of the bit lines to a level that turns off corresponding SGD transistors and inhibit the corresponding memory cells. The memory device can identify a first bit line group and a second bit line group of bit lines within the memory device. For instance, as discussed in more detail below, a local controller of the memory device can identify the first bit line group, and the second bit line group of the bit lines based on characteristics corresponding to the bit lines.

The local controller causes the first bit line group and the second bit line group to separately receive the inhibit voltage (e.g., a bit line voltage) at a first voltage level during a first bit line set (BLSET) phase and a second BLSET phase, respectively. Additionally, during the first BLSET phase, the local controller causes the first bit line group to transition to a floating state. In the floating state, the first voltage level can become a reference voltage level for the first bit line group (e.g., the first bit line group floats at the first voltage level).

The first bit line group and the second bit line group can be coupled (e.g., capacitively coupled) such that, during the second BLSET phase, the voltage level of the first bit line group is boosted to a second voltage level. The voltage level of the first bit line group can be boosted to the second voltage level by the inhibit voltage being applied to the second bit line group. Further, the second voltage level can turn off the SGD transistors and inhibit the memory cells corresponding to the first bit line group.

The memory device described in the present disclosure can boost the voltage level of the portion of the bit lines using capacitive coupling or cross talk between the bit lines. For example, the first bit line group may be capacitively coupled to the second bit line group to boost the voltage level of the first bit line group. This boosting permits the memory device to use a reduced supply voltage to both power the various components within the memory device and as the inhibit voltage without negatively impacting the inhibit efficiency of the memory device. Additionally, this boosting permits the memory device to reduce the overall power consumption of the memory device by using the reduced supply voltage without negatively impacting the inhibit efficiency of the memory device. Details of the technology for boosting the voltage level to increasing inhabit efficiency are further described below.

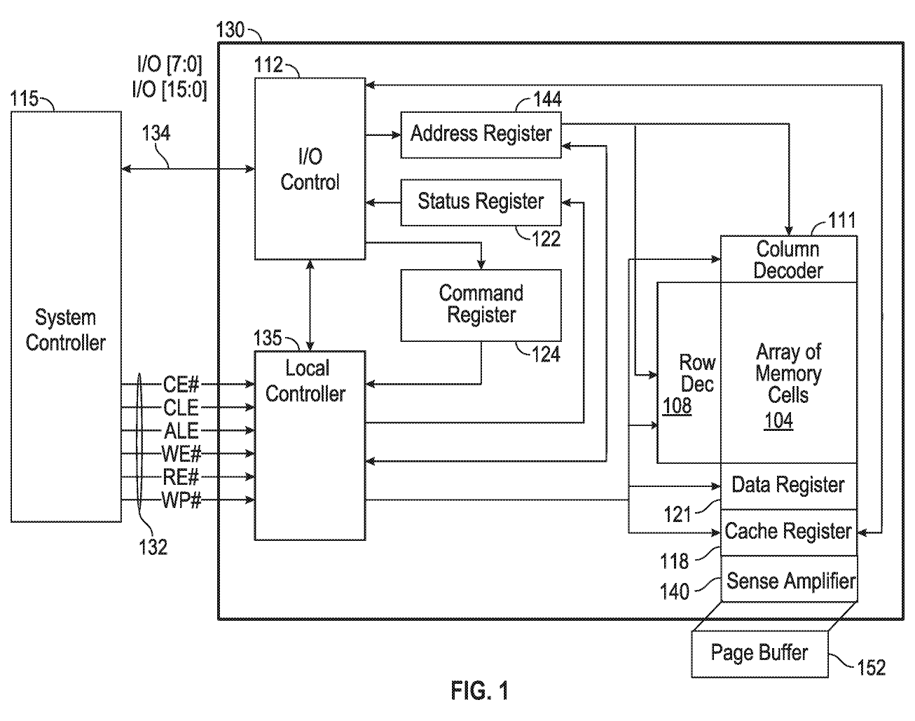

FIG. 1 is a simplified block diagram of a memory device 130 in communication with a system controller 115 of a memory system according to an embodiment. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. The row decode circuitry 108 and the column decode circuitry 111 may simply be referred to as a row decoder 108 and a column decoder 111, respectively. A command register 124 is in communication with the I/O control circuitry 112 and a local controller 135 to latch incoming commands.

A memory controller (e.g., the local controller 135 internal to memory device 130) controls access to the array of memory cells 104 in response to the commands and generates status information for the external system controller 115, i.e., the local controller 135 is configured to perform access operations (e.g., read operations, program operations, and/or erase operations) on the array of memory cells 104. The local controller 135 is in communication with row decode circuitry 108 and the column decode circuitry 111 to control the row decode circuitry 108 and the column decode circuitry 111 according to the addresses.

In some embodiments, the local controller 135 communicates with the external system controller 115, which may be a host controller (e.g., an UFS or eMMC controller, or a CPU communicating with the local controller 135) located in a host system or a memory system controller located in a memory system. In some embodiments, local controller 135 is disposed on the same semiconductor die as the memory array (e.g., array of memory cells 104), and a separate system controller 115 is disposed on a different die. In other examples, some portions of the memory device 130 may be disposed on a first die and other portions of the memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of the memory device 130. Thus, the second die may include the system controller 115, the I/O control circuitry 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, the system controller 115 and the local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

The local controller 135 is also in communication with a cache register 118, a data register 121, and a sense amplifier 140. In some embodiments, one or more cache registers 118 can collectively form at least a part of a cache buffer. The cache register 118 latches or buffers data, either incoming or outgoing, as directed by the local controller 135 to temporarily store data while the array of memory cells 104 is busy writing or reading, respectively, other data. During a program operation (e.g., write operation), data can be passed from the cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to the cache register 118. In some embodiments, the cache register 118 and/or the data register 121 can form at least a portion of a page buffer 152 of the memory device 130. The sense amplifier 140 may be configured to sense a data state of a memory cell of the array of memory cells 104, e.g., by sensing a state of a data line connected to that memory cell. A status register 122 can be in communication with the I/O control circuitry 112 and the local controller 135 to latch the status information for output to the system controller 115.

As shown in FIG. 1, the memory device 130 receives various control signals via the local controller 135 from the system controller 115 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over the control link 132 depending upon the nature of the memory device 130. In one embodiment, the memory device 130 receives command signals (which represent commands), address signals (which represent addresses), and data signals (which represent data) from the system controller 115 over a multiplexed input/output (I/O) bus 134 and outputs data to the system controller 115 over the I/O bus 134.

For example, the commands can be received over input/output (I/O) pins [7:0] of the I/O bus 134 at the I/O control circuitry 112 and can then be written into a command register 124. The addresses can be received over input/output (I/O) pins [7:0] of the I/O bus 134 at I/O control circuitry 112 and can then be written into the address register 144. The data can be received over input/output (I/O) pins [7:0] for an 8-bit device or input/output (I/O) pins [15:0] for a 16-bit device at the I/O control circuitry 112 and then can be written into the cache register 118. The data can be subsequently written into the data register 121 for programming the array of memory cells 104.

In an embodiment, the cache register 118 can be omitted, and the data can be written directly into the data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description uses 16 bits I/O bus 134 as an example, it is understood that the bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

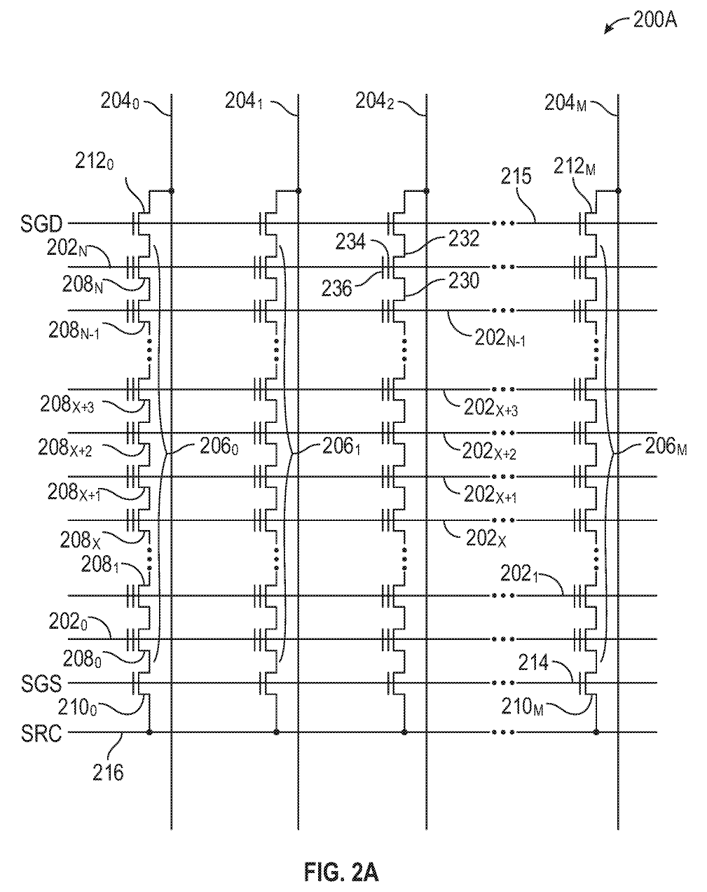

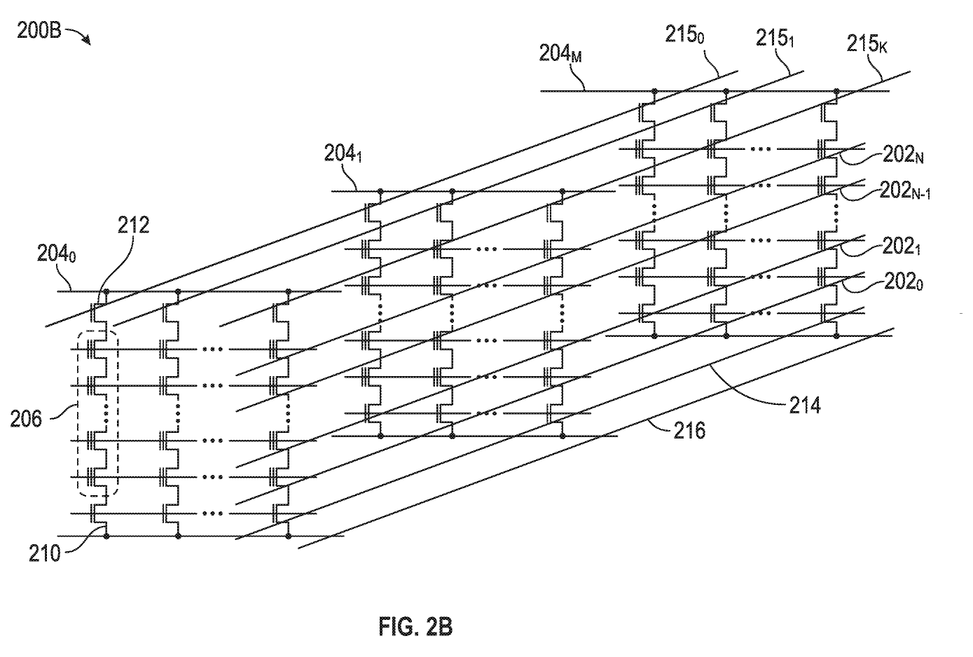

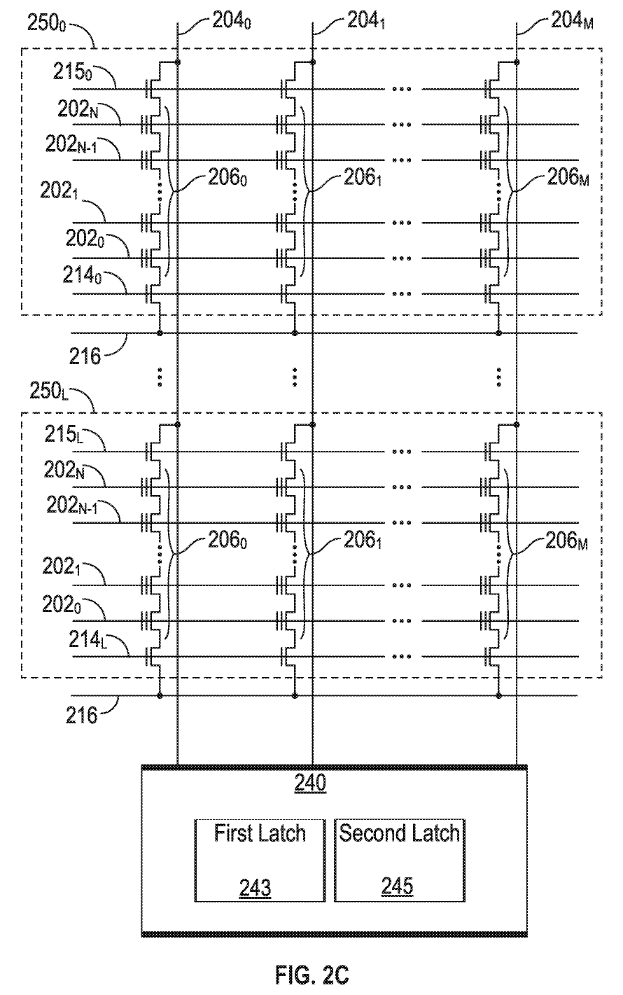

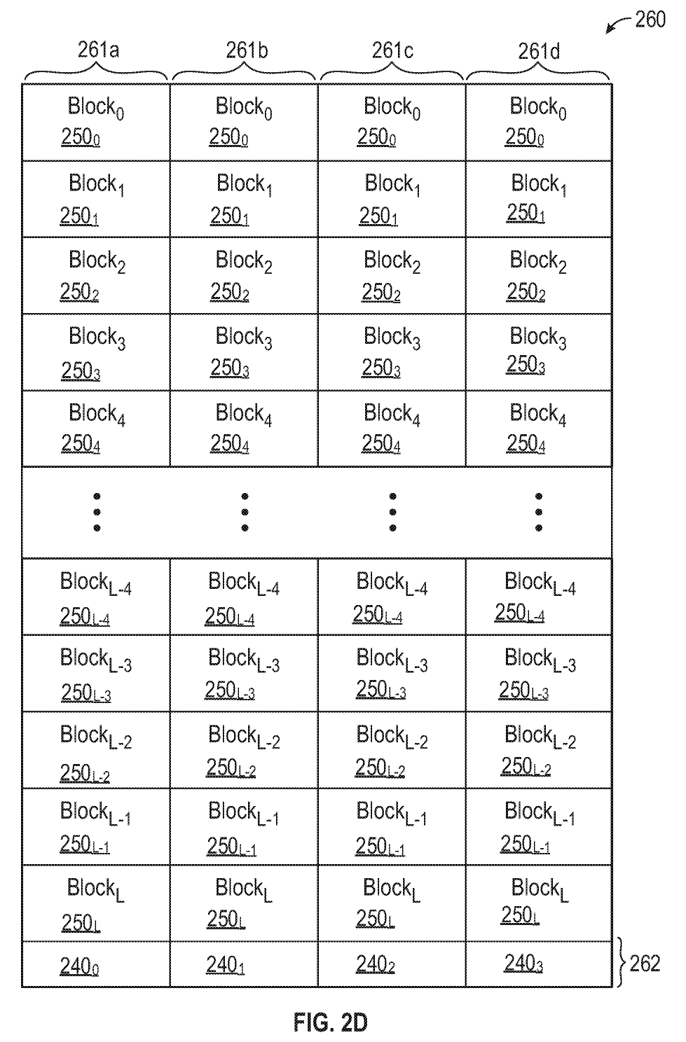

FIG. 2A-2B are example schematics of portions of an array of memory cells 200A, such as a NAND memory array. The array of memory cells 200A may be an example of the array of memory cells 104 of the memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀to 210_{M} (e.g., that can be source select transistors, commonly referred to as select gate source), and a select transistor 212 (e.g., a field-effect transistor), such as one of the select transistors 212₀to 212_{M} (e.g., that can be drain select transistors, commonly referred to as select gate drain). The select gates 210₀to 210_{M} can be commonly connected to a select line 214, such as a source select line (SGS), and the select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, the NAND strings 206, and the bit lines 204 extend in substantially parallel planes. Alternatively, the memory array 200A in FIG. 2A can be a three-dimensional memory array, e.g., where the NAND strings 206 can extend substantially perpendicular to a plane containing the common source 216 and to a plane containing the bit lines 204 that can be substantially parallel to the plane containing the common source 216.

Typical construction of the memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although the bit lines 204₃-204₅ are not explicitly depicted in FIG. 2A, it is apparent from the figure that the bit lines 204 of the array of memory cells 200A can be numbered consecutively from bit line 204₀to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single program operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204. Additionally, the buffer portion 240 can include a first latch 243 and a second latch 245 to apply bias voltages to the bit line 204.

FIG. 2D is a block schematic of a portion of an example array of memory cells 260. Array of memory cells 260 can be used as the array of memory cells 104 in a memory device 130. The array of memory cells 260 is depicted as having four memory planes 261 (e.g., memory planes 261a-261d). Each of the memory planes 261 may refer to a group of memory blocks of memory cells 250. Each memory plane 261 can be in communication with a respective buffer portion 240, which can collectively form a page buffer 262. Page buffer 262 may be used to implement page buffer 152 shown in FIG. 1. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

In some cases, concurrent operations may be performed on different planes. For example, concurrent operations may be performed on memory cells within different blocks 250 so long as the different blocks 250 are in different planes 261. In some cases, an individual memory block 250 may be referred to as a physical block, and a virtual block may refer to a group of blocks 250 within which concurrent operations may occur. For example, concurrent operations may be performed on four blocks of 250₀ that are within planes 261a, 261b, 261c, and 261d, respectively, and the four blocks of 250₀ may be collectively referred to as a virtual block. In some cases, a virtual block may include blocks from different memory devices. In some cases, the physical blocks within a virtual block may have the same block address within their respective planes. In some cases, performing concurrent operations in different planes 261 may be subject to one or more restrictions, such as concurrent operations being performed on memory cells within different pages that have the same page address within their respective planes 261 (e.g., related to command decoding, page address decoding circuitry, or other circuitry being shared across planes 261).

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

With continued reference to FIGS. 1 and 2A-2C, during a true erase operation (during which memory cells are actually being erased), the local controller 135 (e.g., using an erase operation manager 137) can cause a common source voltage line, e.g., the SRC 216 (FIG. 2A), to be ramped to an erase voltage (VERA) with an erase pulse while the select gates 210₀ to 210_{M} (SGS transistors) are turned on. Ramping to this high bias erase voltage, and the subsequent recovery from this voltage ramping, may take a significant amount of time. Concurrently, the erase operation manager 137 can cause the select gates 212₀ to 212ₘ (FIG. 2A) to be turned off to enable the drains of the select gates 212₀ to 212ₘ to float, which causes the bit lines 204₀ to 204_{M} to also float. Further, the erase operation manager 137 can couple the word lines 202 (FIG. 2A) to ground, e.g., zero volts, or retain the word lines 202 at a low voltage. This set of voltage levels at the memory array 200A can create an erase potential that causes the memory cells 208₀to 208_{N} to be erased, e.g., forces electrons to exit through a body of each memory cell and out the floating bit lines 204₀ to 204_{M}. In other embodiments, the reverse can be done so the select gates 210₀ to 210_{M} are turned off, causing the SRC line 216 to float while the voltage of the bit lines are ramped to Vera while the select gates 212₀ to 212_{M} are turned on. As mentioned earlier, in 3D NAND, one of the channel region, pillar, or bit line can also be ramped up in voltage to cause erasure of attached memory cells. In some embodiments, one or more sub-blocks, to include a physical block, of memory cells are erased during the same true erase operation. A block of memory cells can be generally understood to include four or more sub-blocks, wherein each sub-block includes a separate string of memory cells.

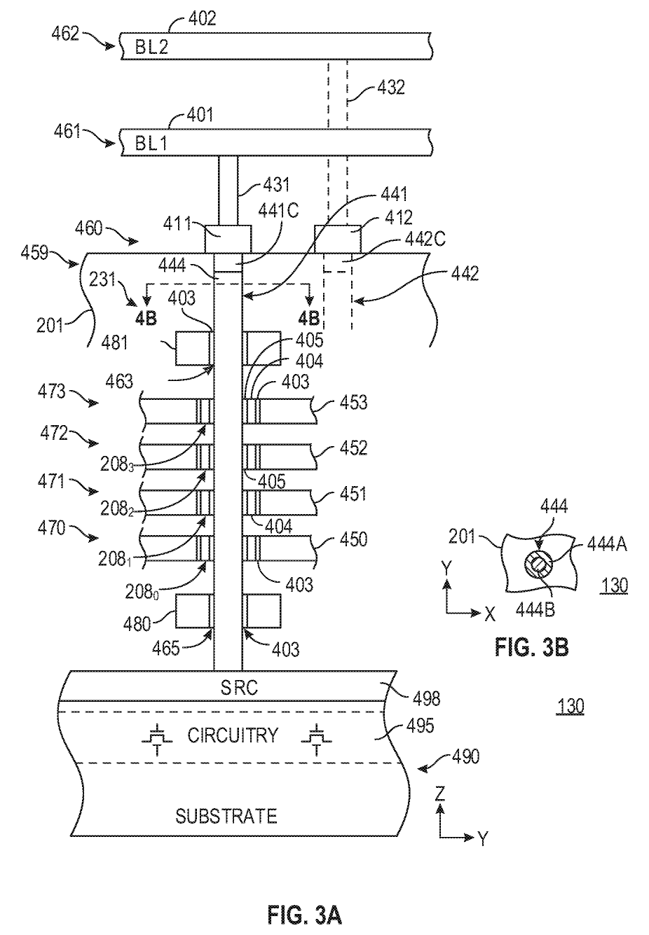

FIG. 3A shows a side view (e.g., a cross section with respect to the X-Z directions) of a portion of the three-dimensional structure of memory device 130 including a structure of memory cell string 231 (e.g., a NAND string) having a pillar 441, according to some embodiments described herein. FIG. 3A shows the structure of one memory cell string (e.g., memory cell string 231) of memory device 130. However, other memory cell strings (e.g., NAND strings 206₀ – 206_{M} in FIG. 2A and NAND strings 206 in FIG. 2B) can have a similar or the same structure as memory cell string 231 shown in FIG. 3A.

Starting from the top of FIG. 3A, memory device 130 have data lines 401 and 402 (e.g., corresponding to bit lines 204 in FIGS. 2A, 2B, and 2C) coupled to conductive structures 431 and 432, respectively, and coupled to conductive contacts 411 and 412, respectively. Data lines 401 and 402 are therefore electrically connected to pillars 441 and 442, respectively, via the conductive contacts 411 and 412, respectively. It is understood that memory device 130 can include many other similar data lines, conductive structures, and conductive contacts, which are not shown for simplicity.

FIG. 3A shows directions X, Y, and Z that can be relative to the physical directions (e.g., dimensions) of the structure of memory device 130. For example, the Z-direction can be a direction perpendicular to (e.g., vertical direction relative to) a substrate (e.g., a semiconductor substrate) of memory device 130. The Z-direction is perpendicular to the X-direction and Y-direction (e.g., the Z-direction is perpendicular to an X-Y plane of memory device 130).

As shown in FIG. 3A, data lines 401 and 402 can carry signals (e.g., bit line signals) BL1 and BL2, respectively. In the physical structure of memory device 130, data lines 401 and 402 can be structured as conductive lines and have respective lengths extending in the Y-direction. The data lines (e.g., data lines 401 and 402) of memory device 130 can be formed on different levels (e.g., layers) in the physical structure of memory device 130. For example, data lines 401 can be formed on one level (e.g., a lower level 461) of memory device 130, and data lines 402 can be formed on another level (e.g., an upper level 462) of memory device 130. Although not shown in FIG. 3A, multiple data lines can be located side-by-side in any particular level. For example, level 461 may have multiple data lines and level 462 may also have multiple data lines. Data lines in the same level can be separated from each other by a distance (e.g., a gap) in the X-direction. The gaps between data lines in the same level may be the same or different. As shown in FIG. 3A, each of data lines 401 and 402 can have a thickness in the Z-direction and a width in the X-direction. Each of the thickness (in the Z-direction) and the width (in the X-direction) is less than the length (in the Y-direction). The thickness can be less than, equal to, or greater than the width.

In FIG. 3A, each of conductive structures 431 and 432 can have a length extending in the Z-direction. In some examples, the length of conductive structure 431 can be less than the length of conductive structure 432, because level 461 is a lower level that is located closer to memory array 201. Each of conductive structures 431-432 can include (e.g., can be formed from) a conductive material that extends in the Z-direction. Examples of the conductive material include metal, alloy, conductively doped polysilicon, or other conductive materials. Although not shown in FIG. 3A, memory device 130 can include a dielectric material (e.g., silicon dioxide) formed between levels 462 and 461. The dielectric material can be formed before conductive structures 431 and 432. Then, openings (e.g., holes (e.g., vertical vias)) can be formed in the dielectric material. The material of each of conductive structures 431-432 can be formed (e.g., deposited) inside a respective opening of the openings.

As shown in FIG. 3A, each of conductive structures 431 and 432 can be coupled to (e.g., in electrical contact with) a respective conductive contact among conductive contacts 411 and 412 and coupled to (e.g., in electrical contact with) a respective data line among data lines 401 and 402. For example, conductive structure 431 can include an end (e.g., bottom end) coupled to (e.g., directly contacting) conductive contact 411, and another end (e.g., top end) coupled to (e.g., directly contacting) data line 401. In another example, conductive structure 432 can include an end (e.g., bottom end) coupled to (e.g., directly contacting) conductive contact 412, and another end (e.g., top end) coupled to (e.g., directly contacting) data line 402.

As shown in FIG. 3A, memory cell string 231 can include pillars (e.g., vertical pillars) 441 and 442. Pillars 441 and 442 can include pillar contacts 441C and 442C, respectively, located on the same level (e.g., level 459) of memory device 130. Pillars 441 and 442 can be located under (e.g., directly under) respective conductive contacts 411 and 412, which are under (e.g., directly under) respective conductive structures 431 and 432. Conductive structures 431 and 432 can be coupled to (e.g., in electrical contact with) pillars 441 and 442, respectively, through conductive contacts 411 and 412, respectively. Thus, as shown in FIG. 3A, data lines 401 and 402 can be coupled to (e.g., electrically coupled to) pillars 441 and 442, respectively, through respective conductive structures 431 and 432 and respective conductive contacts 411 and 412.

As described above, data lines 401 and 402 are located in levels 461 and 462, respectively. Levels 461 and 462 are in portion of memory device 130 that is located above memory array 201 in the Z-direction. Memory array 201 is located above a substrate 490 of memory device 130 in the Z-direction. As described above, a memory array such as memory array 201 comprises multiple memory cell strings (one of which is shown as memory cell string 231).

As shown in FIG. 3A, pillar (e.g., a vertical pillar) 441 can be a part of memory cell string 231 and can have a length extending in the Z-direction (e.g., extend vertically with respect to substrate 490). Pillar 441 can extend through memory cells 208₀, 208₁, 208₂, and 208₃ of memory cell string 231. Pillar 441 can include (e.g., can be formed from) a conductive material (e.g., conductively doped polysilicon). Each of memory cells 208₀, 208₁, 208₂, and 208₃ can include a structure of transistor (e.g., a memory cell transistor). Part of pillar 441 can form the channel region (e.g., to conduct current) of the transistor of each memory cells 208₀, 208₁, 208₂, and 208₃. It is understood that while FIG. 3A only shows four memory cells 208₀-208₃ , memory cell string 231 can include any number of memory cells that share a same pillar (e.g., pillar 441).

As described above, pillar contact 441C can be formed from conductively doped polysilicon, metal, or other conductive materials. Pillar 441 can include a portion 444. Pillar contact 441C and portion 444 of pillar 441 can include the same conductive material or different conductive materials. Conductive structure 431, conductive contact 411, and pillar 441 can be part of a circuit path (e.g., a conductive channel of memory cell string 231) between data line 401 and a conductive region 498 (associated with an SRC line). Conductive region 498 can be a part of a common source line (e.g., common source line or source plate 216 in FIG. 2A). Conductive structure 431 and pillar 441 can have the same material or different materials. In FIG. 3A, during a memory operation (e.g., read or write operation) of memory device 130, a circuit path (e.g., a current path) can be formed between data line 401 and conductive region 498 through conductive structure 431, conductive contact 411, and pillar 441 (which includes pillar contact 441C and portion 444 of pillar 441).

Substrate 490 of memory device 130 can include a semiconductor substrate (e.g., silicon-based substrate). For example, substrate 490 can include a p-type silicon substrate or an n-type silicon substrate. As shown in FIG. 3A, memory cells 208₀, 208₁, 208₂, and 208₃ of memory cell string 231 can be located along (e.g., adjacent) respective portions of pillar 441 in different levels (in the Z-direction) of memory device 130. For example, memory cells 208₀, 208₁, 208₂, and 208₃ can be located one over another (e.g., formed vertically) in levels 470, 471, 472, and 473, respectively, of memory device 130. Memory cells of other memory cell strings of memory device 130 can also be located on respective levels 470, 471, 472, and 473.

By stacking the memory cells in different levels, the memory device forms a 3D structure that has a higher capacity than a 2D device. In a typical 3D memory device (e.g., device 130 shown in FIG. 3A), for example, multiple levels (e.g., levels 470, 471, 472, and 473) are stacked together with one or more memory pillars (e.g., pillars 441 and 442) disposed vertically in the middle. The memory pillars may act as the channel region of the memory device. The multiple levels (e.g., layers or tiers) of the memory device may form groups or decks. A deck of a 3D memory device may be processed together (e.g., patterned and/or etched together) when forming the memory pillar associated thereof. A level of the memory device may have one or more access lines (e.g., word lines) or access line groups (e.g., word line groups). Each deck may have one or more access line segments (e.g., word line segments). An access line segment may have fewer or more access lines than those in a deck. For example, a deck may have two word line segments distributed in one or more levels. In some cases, certain memory operations (e.g., an erase operation) can be performed to a word line group (e.g., a deck), and not to the entire memory block. By not performing an operation to the entire memory block, the particular operation may be performed faster.

FIG. 3A further illustrates that access lines 450, 451, 452, and 453 of memory device 130 can be located along (e.g., adjacent) respective portions (in the Z-direction) of pillar 441 in the same levels (e.g., levels 470, 471, 472, and 473, respectively) that memory cells 208₀, 208₁, 208₂, and 208₃ are located. Access lines can include, for examples, word lines or control gates. Access lines 450, 451, 452, and 453 can include (e.g., can be formed from) a conductive material (or materials). Example materials for access lines 450, 451, 452, and 453 include metal, alloy, doped polysilicon, other conductive materials.

In FIG. 3A, a select line (e.g., drain select gate or SGD) 481 can have a length extending in the X-direction (e.g., perpendicular to the lengths (in the Y-direction) of data lines 401 and 402). The materials of select line 481 can include a conductive material (e.g., conductively doped polysilicon, metal, other conductive material). FIG. 3A shows an example where another select line (e.g., source select gate or SGS) 480 can have a structure (e.g., shape, material, or both) similar to (or the same as) that of select line 481. In some examples, select line 480 can have a structure (e.g., shape, material, or both) similar to (or the same as) that of each of access lines 450, 451, 452, and 453.

As shown in FIG. 3A, a transistor (e.g., source select transistor) 465 and a transistor (e.g., drain select transistor) 463 can be located along (e.g., adjacent) respective portions of pillar 441 in the Z-direction. Memory cells 208₀, 208₁, 208₂, and 208₃ of memory cell string 231 can be located along the portion of pillar 441 that is between transistors 465 and 463.

Memory cell string 231 can include materials 403, 404, and 405 formed between portion 444 of pillar 441 and a respective access line among access lines 450, 451, 452, and 453. Material 403 can also be formed between pillar 441 and each of select lines 480 and 481. Materials 403, 404, and 405 located at a particular memory cell (among memory cells 208₀, 208₁, 208₂, and 208₃) can be a part (e.g., a memory element) of that particular memory cell. As shown in FIG. 3A, the combination of materials 403, 404, and 405 of a memory cell (among memory cells 208₀, 208₁, 208₂, and 208₃) can be separated from (in the Z-direction) the combination of materials 403, 404, and 405 of another memory cell (among memory cells 208₀, 208₁, 208₂, and 208₃).

Material 403 can include a charge blocking material (or charge blocking materials), for example, a dielectric material (e.g., silicon nitride) that is capable of blocking a tunneling of a charge. Material 404 can include a charge storage material (or charge storage materials) that can provide a charge storage function to represent a value of information stored in memory cells 208₀, 208₁, 208₂, and 208₃. For example, material 404 can include polysilicon (e.g., conductively doped polysilicon), which can be either a p-type polysilicon or an n-type polysilicon. The polysilicon can be configured to operate as a floating gate (e.g., to store charge) in a memory cell (e.g., a memory cell 208₀, 208₁, 208₂, and 208₃). In another example, material 404 can include a dielectric material (e.g., silicon-nitride based material or other dielectric materials) that can trap charge in a memory cell (e.g., a memory cell 208₀, 208₁, 208₂, and 208₃). Material 405 can include a tunnel dielectric material (or tunnel dielectric materials), for example, silicon dioxide, that is capable of allowing tunneling of a charge (e.g., electrons).

As shown in FIG. 3A, memory device 130 can include circuitry 495 located (e.g., formed) under memory array 201 (e.g., located directly under memory cell string 231). Circuitry 495 can include circuit elements (e.g., transistors T) coupled to other circuit elements (e.g., coupled to data lines 401-402) of memory device 130. The circuit elements (e.g., transistors T) of circuitry 495 can be configured to perform part of a function of a memory device (e.g., memory device 130). For example, circuitry 495 can include decoder circuits, driver circuits, buffers (e.g., page buffers), sense amplifiers, charge pumps, and other circuitry of memory device 130. In an alternative structure of memory device 130, circuitry 495 can be located (e.g., formed) above memory array 201 (instead of under memory array 201). For example, in the alternative structure of memory device 130, circuitry 495 can be located above memory array 201 and under data lines 401 and 402, or located between data lines 401 and 402 of memory array 201 in the Z-direction. In another example, in the alternative structure of memory device 130, circuitry 495 can be located above memory array 201 and above data lines 401 and 402 in the Z-direction.

A different view of pillar 441 along a cross-sectional line 4B-4B is shown in FIG. 3B. FIG. 3B shows a top view (e.g., a cross section with respect to the X-Y plan) of portion 444 of pillar 441 along line 4B-4B of FIG. 3A. As shown in FIG. 3B, portion 444 of pillar 441 can include material 444A and material 444B surrounded by material 444A. Material 444A can be (or can include) a part of a conductive structure (e.g., a conductive channel) of pillar 441. Material 444B can include a dielectric material. In an alternative structure of pillar 441, material 444B can be omitted from pillar 441, such that the entire portion 444 of pillar 441 can include material 444A (without material 444B).

As discussed above, the inhibit efficiency of the memory device 130 can be impacted by relationships between the inhibit voltage, the SGD gate voltage, and the SGD Vt distributions of the select transistors 212. In addition, as discussed above, these factors impact the inhibit efficiency of the memory device 130 because a difference between the level of the SGD gate voltage and the level of the inhibit voltage needs to be lower than or equal to the corresponding SGD Vt distribution to inhibit a corresponding memory cell of the array of memory cells 104.

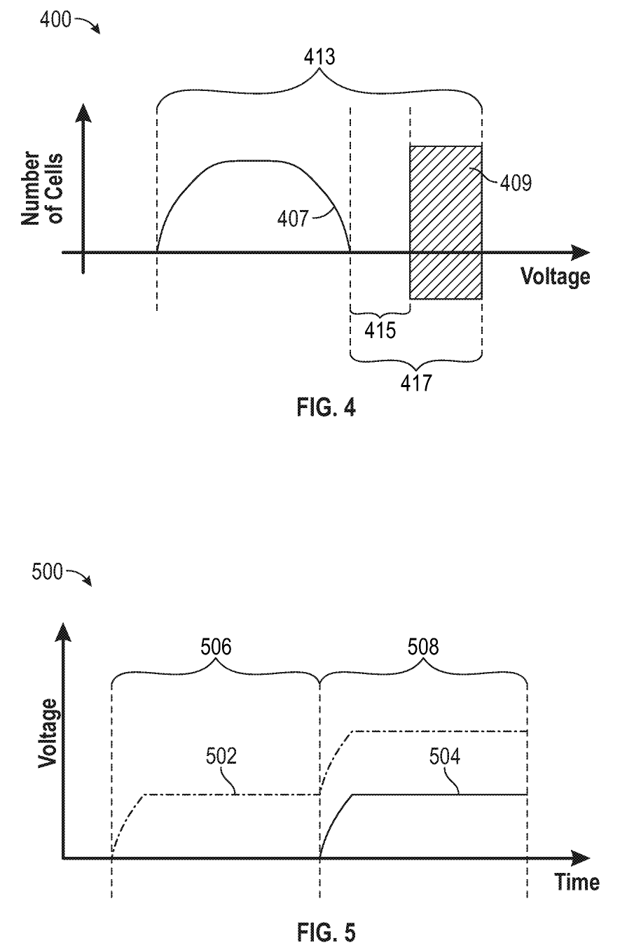

FIG. 4 illustrates a graphical representation 400 of an example SGD Vt distribution 407 and a relationship between various voltage ranges 409, 413, b, and 417 for the inhibit voltage or the SGD bias gate voltage. In the graphical representation 400, the vertical or Y axis represents a number of memory cells in the memory array and the horizontal or X axis represents voltage. The SGD Vt distribution 407 may correspond to any threshold voltage distributions of the select transistors 212₀ to 212_{M} discussed above.

In FIG. 4, the voltage range 409 represents an available range of voltage levels for SGD transistor biasing at the gate of the SGD transistor. The SGD Vt distribution 407 has a range with a lower end (denoted as Vt_sgd_lower) and an upper end (denoted as Vt_sgd_upper). If the gate biasing voltage of the SGD transistor exceeds the voltage range 409, inhibit may fail because the SGD transistor may be turned on. Thus, if the lower end of the SGD Vt distribution 407 is denoted as Vt_sgd_lower and the inhibit voltage is the power supply voltage Vcc, the difference between Vsgd and Vcc must be no greater than the Vt_sgd_lower (e.g., Vsgd<= Vt_sgd_lower + Vcc). The voltage range 413 in FIG. 4 represents such a range of voltage levels of Vsgd. In some situations, there should be a margin of voltage levels between the upper end of the SGD Vt distribution 407 and the available range of the gate biasing voltage of the SGD transistor 409. The voltage range 415 represents such a margin of voltage levels (also denoted as Vsspc). In some embodiments, the margin (i.e., the difference between lower end of the available range of the gate biasing voltage Vsgd 409 and the upper end of the SGD Vt distribution 407) can be configured to be greater than a non-zero value (e.g., Vsgd >= Vt_sgd_upper + Vsspc). t In FIG. 4, the voltage range 417 represents such margin Vsspc.

As shown in FIG. 4, if the inhibit voltage (e.g., the power supply voltage Vcc) goes lower, the SGD bias voltage 409 may also need to go lower to prevent inhibit failure. If the SGD Vt distribution 407 becomes wider, the inhibit voltage may need to go up to compensate for the wider distribution. This also affects the Vsspc range limitation. For example, the difference between the gate bias voltage of the SGD transistor and the threshold voltage Vt cannot be zero or negative (e.g., it should have a positive margin). Thus, a memory cell that has lower SGD Vt distribution may have more risk to degrade the E0 level in terms of the power supply voltage Vcc and the wide SGD Vt distribution.

With continued reference to FIGS. 1-3B, to address the technical challenges described above, in some embodiments of the present technology, during the program operation of the array of memory cells 104, the local controller 135 may identify two or more groups of the bit lines 204 for boosting the inhibit voltage biasing of at least one group of the bit lines 204. In some embodiments, the local controller 135 may identify the groups of the bit lines 204 based on characteristics corresponding to the bit lines 204. Example characteristics corresponding to the bit lines 204 are discussed below.

The local controller 135 may identify the groups of the bit lines 204 in accordance with multiple program loops of the program operation being completed. For example, the local controller 135 can identify the groups of the bit lines 204 after completion of two, three, four, five, six, or more program loops. The local controller 135 may identify the groups of the bit lines 204 in accordance with the multiple program loops being completed because a number of the bit lines 204 that correspond to memory cells that are still to be programmed for later program loops may be reduced compared to earlier program loops.

In some embodiments, the characteristic corresponding to the bit lines 204 may include the Vt distributions (e.g., the SGD Vt distributions) of the select transistors 212 coupled to the corresponding bit lines 204. The local controller 135 may obtain the Vt distributions of the select transistors 212 that are coupled to the corresponding bit lines 204 from a user or other external source. Alternatively, the local controller 135 may determine and verify the Vt distributions of the select transistors 212 that are coupled to the corresponding bit lines 204 in accordance with any appropriate technique or method. The local controller 135 may cause the Vt distributions to be stored in the registers (e.g., the data register 121 or the cache register 118) of the page buffer 152.

In some embodiments, the local controller 135 may obtain the Vt distributions of the select transistors 212 or determine and verify the Vt distributions of the select transistors during the program operation. Alternatively, the local controller 135 may obtain the Vt distributions of the select transistors 212 or determine and verify the Vt distributions of the select transistors prior to the program operation. For example, the local controller may obtain the Vt distributions of the select transistors 212 or determine and verify the Vt distributions of the select transistors during a previous erase cycle.

In some instances, the local controller 135 may compare the Vt distributions of the select transistors 212 to each other and assign the Vt distributions to multiple groups based on the comparison. As a first example, the local controller 135 can compare the Vt distributions of the select transistors 212₀-212₃ to each other; assign the Vt distributions of the select transistors 212₀and 212₃ to a first group based on similarities between these Vt distributions; and assign the Vt distributions of the select transistor 212₁ and 212₂ to a second group based on similarities between these Vt distributions. As a second example, the local controller 135 can assign the Vt distributions of the select transistors 212₁ and 212₃ to the first group based on these Vt distributions being less than the Vt distributions of the select transistor 212₂ and 212₄.

In these and other instances, the local controller 135 may identify the groups of the bit lines 204 based on the groups to which the corresponding Vt distributions have been assigned. Referring to the first example discussed above, the local controller 135 may identify the bit lines 204₀ and 204₃ as the first bit line group based on the Vt distributions of the select transistors 212₀ and 212₃ being assigned the first group and the bit lines 204₁ and 204₂ as the second bit line group based on the Vt distributions of the select transistor 212₁ and 212₂ being assigned to the second group. Referring to the second example discussed above, the local controller 135 may identify the bit lines 204₁ and 204₃ as the first bit line group based on the Vt distributions of the select transistors 212₁ and 212₃ being assigned the first group and the bit lines 204₀ and 204₂ as the second bit line group based on the Vt distributions of the select transistor 212₀ and 212₂ being assigned to the second group.

In some instances, the local controller 135 may assign the Vt distributions to the multiple groups such that a particular number of the bit lines 204 are to be identified as the first bit line group. For example, the local controller 135 can assign the Vt distributions such that ten of the bit lines 204 are to be identified as the first bit line group. Alternatively, the local controller 135 may assign the Vt distributions to the multiple groups such that a percentage of the bit lines 204 are to be identified as the first bit line group. For example, the local controller 135 can assign the Vt distributions such that forty percent of the bit lines 204 are to be identified as the first bit line group.

In some instances, the local controller 135 may compare the Vt distributions of the select transistors 212 to a threshold value to identify the groups of the bit lines 204. For example, the local controller 135 can identify the bit lines 204 that correspond to Vt distributions that are equal to or below the threshold value as the first bit line group and can identify the bit lines 204 that correspond to Vt distributions that are greater than the threshold value as the second bit line group. For example, if the threshold value is 2.2V; the Vt distribution of the select transistor 212₀ is equal to 1.9 V; and the Vt distribution of the select transistor 212₁is equal to 2.7 V, the local controller 135 identifies the bit line 204₀ as the first bit line group and identifies the bit line 204₁ as the second bit line group.

In some embodiments, the local controller 135 may determine the threshold value for identifying the groups of bit lines based on the Vt distributions of the select transistors 212. For example, the Vt distribution can be equal to an average of the Vt distributions of a portion or all the select transistors 212. As another example, the threshold value can be equal to the Vt distribution of a randomly chosen select transistor 212. In other embodiments the local controller 135 may determine the threshold value for identifying the groups of bit lines based on user input. For example, the user input can indicate a voltage value that is to be used as the threshold value. As another example, the user input can identify a particular select transistor 212 and the local controller 135 can use the Vt distribution of the particular select transistor 212 as the threshold value. Alternatively, the threshold value may be programmed in the memory device 130. For example, the threshold value can be programmed in the memory device 130 during manufacturing, at initiation, during an erase operation, or during other access operations of the memory device 130. In some embodiments, if all the Vt distributions of the select transistors 212 are less than or greater than the threshold value, the local controller 135 may adjust the threshold value accordingly. For example, if all the Vt distributions of the select transistors 212 are below the threshold value, the local controller 135 can increase the threshold value until at least a portion of the Vt distributions of the select transistors are equal to or greater than the threshold value.

In some instances, the local controller 135 may identify the groups of the bit lines 204 based on an arrangement of the bit lines 204. For example, the local controller 135 may identify the groups of the bit lines 204 based on a number or other identifier of the bit lines 204, the select transistors 212, or both. As another example, the local controller 135 may identify the groups of the bit lines 204 based on a physical location of the various bit lines 204 within the memory device 130. As yet another example, the local controller 135 may randomly identify the groups of the bit lines 204 based on the arrangement of the bit lines 204.

Examples of the local controller 135 identifying the groups of the bit lines 204 based on numbers or identifiers of the bit lines 204 will now be discussed. One example includes the local controller 135 identifying at least a portion of the bit lines 204 associated with even numbers (e.g., the bit lines 204₀, 204₂, or 204₄) as the first group of bit lines and identifying at least a portion of the bit lines 204 associated with odd numbers (e.g., the bit lines 204₁, 204₃, or 204₅) as the second group of bit lines. Another example includes the local controller 135 identifying a first portion of the bit lines 204 that are grouped numerically (e.g., the bit lines 204₀, 204₁, or 204₃) as the first group of bit lines and identifying a second portion of the bit lines 204 that are grouped numerically (e.g., the bit lines 204₄, 204₅, or 204₆) as the second group of bit lines.

Examples of the local controller 135 identifying the groups of the bit lines 204 based on the physical location of the various bit lines 204 within the memory device 130 will now be discussed. One example includes the local controller 135 identifying a portion of the bit lines 204 that are close in proximity (e.g., neighboring bit lines) to each other (e.g., the bit lines 204₀ and 204₁) as the first bit line group. Another example includes the local controller 135 identifying a portion of the bit lines 204 on a first side or in a first part of the memory device 130 as the first bit line group and another portion of the bit lines on a second side or in a second part of the memory device 130 as the second bit line group.

In some instances, the local controller 135 may identify the groups of the bit lines 204 based on user input. The user input may indicate or otherwise identify portions of the bit lines 204 that are to be in the first bit line group or the second bit line group. For example, the user input can indicate that the bit lines 204₁ and 204₂ are to be identified as the first bit line group and can indicate that the bit lines 204₃ and 204_{M} are to be identified as the second bit line group.

In some embodiments, based on the identified groups, the local controller 135 causes the page buffer 152 to apply the inhibit voltage (e.g., the supply voltage) to the first bit line group and the second bit line group during a bit line set (BLSET) portion of a corresponding program loop. In addition, the local controller 135 may separate the BLSET portion of the corresponding program loop into multiple BLSET phases. For example, the local controller 135 can cause the page buffer 152 to apply the inhibit voltage to the first bit line group during a first BLSET phase. As another example, the local controller 135 can cause the page buffer 152 to apply the inhibit voltage to the second bit line group during a second BLSET phase.

During the first BLSET phase, the first bit line group receives the inhibit voltage (e.g., the bit line voltage) at a first voltage level. The first voltage level may be equal to or similar to the voltage level of the inhibit voltage and may be less than a bias voltage applied to gates of a corresponding portion of the select transistors 212. In some embodiments, the first voltage level may be equal to or less than two volts.

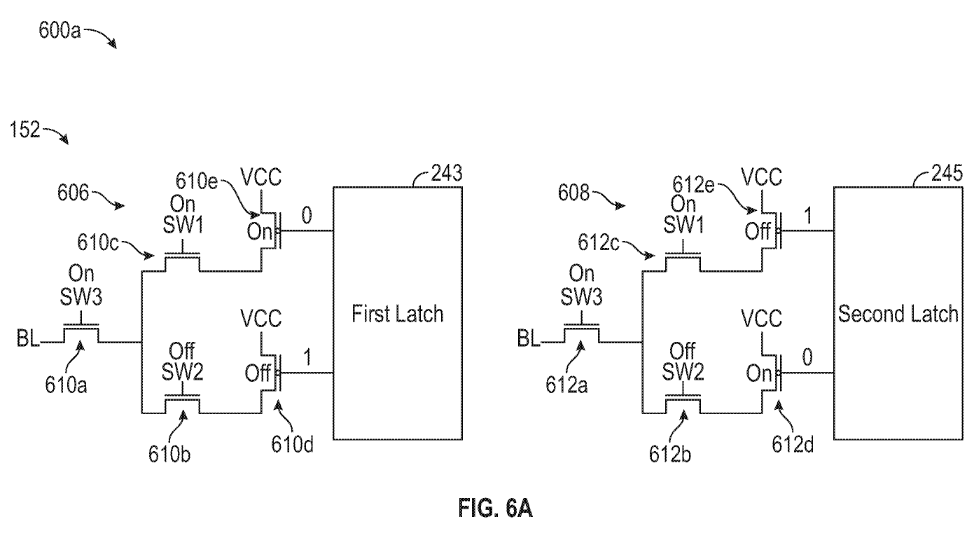

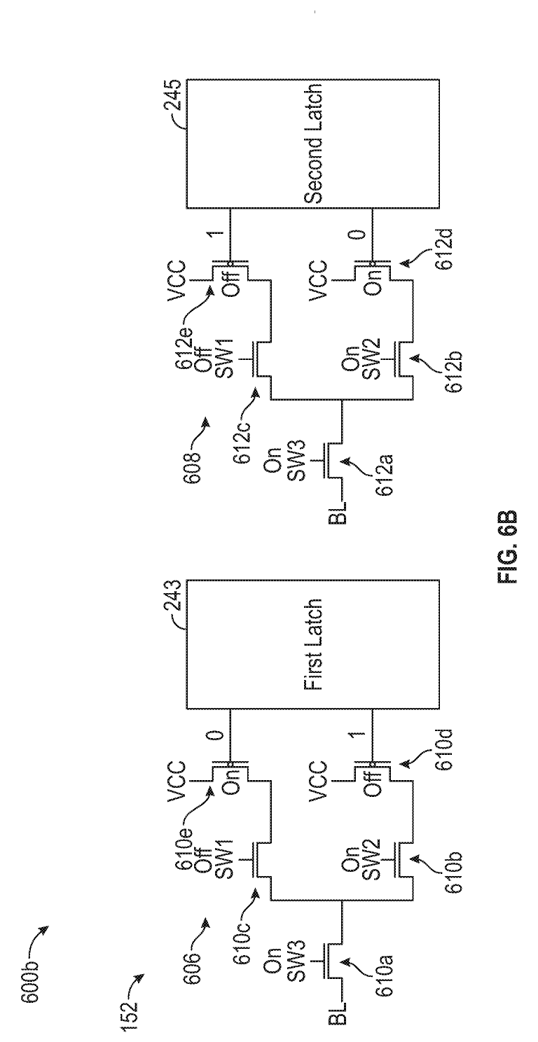

In addition, during the first BLSET phase, the local controller 135 causes the first bit line group to transition to a floating state such that the first bit line group is electrically isolated. Additionally or alternatively, the local controller 135 causes the first bit line group to transition to the floating state such that a voltage level of the first bit line group stays at the first voltage level during the second BLSET phase. To cause the first bit line group to transition to the floating state, the local controller 135 can cause one or more corresponding paths of transistors in the page buffer 152 and/or other switches to turn off. For example, with reference to FIGS. 1, 6A, and 6B, the local controller 135 can cause a first path 606 of transistors 610a-e to turn off. The first path 606 is described in more detail below. The bit lines and the pillars associated with the one or more corresponding paths of transistors are therefore isolated and floating.

In some instances, the first bit line group may transition to the floating state such that the first voltage level becomes a reference voltage for the first bit line group. In other words, the first bit line group may transition to the floating state so that the corresponding bit lines 204 float at or around the first voltage level.

During the second BLSET phase, the first bit line group remains in the floating state at floating at the first voltage level. In addition, the second bit line group receives the inhibit voltage at the first voltage level. The second bit line group receiving the inhibit voltage at the first voltage level may inhibit the corresponding memory cells from being programmed. Further, the second bit line group and the first bit line group may be capacitively coupled such that the second bit line group receiving the inhibit voltage boosts that voltage level of the first bit line group. For example, the voltage of the first bit line group can be boosted from the first voltage level to a second voltage level. The second voltage level is greater than the first voltage level to inhibit the memory cells corresponding to the first bit line group from being programmed.

The above-described boosting process is further illustrated using FIG. 5. FIG. 5 illustrates a graphical representation 500 of a BLSET portion of a program loop. In the graphical representation 500, the vertical or Y axis represents a voltage level, and the horizontal or X axis represents time. As shown in FIG. 5, the BLSET portion includes a first BLSET phase 506 and a second BLSET phase 508.

During the first BLSET phase 506, the local controller 135 causes the inhibit voltage to be applied to the first bit line group and a voltage level—curve 502—of the first bit line group increases from a ground level (e.g., the X axis) to the first voltage level (e.g., the flat portion of the curve 502 within the first BLSET phase 506). As discussed above, during the first BLSET phase 506, the local controller 135 causes the first bit line group to transition to the floating state and stay at the first voltage level.

During the second BLSET phase 508, the local controller 135 causes the inhibit voltage to be applied to the second bit line group and a voltage level—curve 504—of the second bit line group increases from the ground level to the first voltage level (e.g., the flat portion of the curve 504 within the second BLSET phase 508). In addition, during the second BLSET phase 508, the first bit line group and the second bit line group may experience cross talk to boost the voltage level—curve 504—of the first bit line group to a second voltage level. In other words, the first bit line group and the second bit line group are capacitively coupled during the second BLSET phase 508 to boost the voltage level—curve 504—of the first bit line group to the second voltage level (e.g., the flat portion of the curve 502 within the second BLSET phase 508). Crosstalk is generally not desired in circuit design, and usually considered noise or interference. However, crosstalk between two-bit line groups can be used to boost the voltage level of one group without actually having to apply a higher voltage to the particular bit line group. Therefore, crosstalk in the present technology is desired for preventing the inhibit failure and for improving the inhibit efficiency and in turn the programming efficiency.

In some embodiments, a coupling ratio between the first bit line group and the second bit line group may be equal to or less than ninety five percent. For example, if the voltage level of the inhibit voltage is equal to two volts (e.g., the first voltage level is equal to two volts) and the coupling ratio is equal to ninety percent, the second voltage level is equal to 1.8 V.

With reference back to FIGS. 1-3B, the local controller 135 may cause different latches of the page buffer 152 to apply the inhibit voltage to the first bit line group and the second bit line group. For example, the first latch 243 may correspond to the first bit line group and can apply the inhibit voltage to the first bit line group and the second latch 245 may correspond to the second bit line group and can apply the inhibit voltage to the second bit line group. In some embodiments, the first latch 243 and/or the second latch 245 may include or be coupled to one or more sense amplifiers (e.g., sense amplifier 140). Each of the first latch 243 and the second latch 245 may apply the inhibit voltage to the first bit line group and the second bit line group using different paths.

FIGS. 6A and FIG. 6B illustrate different example arrangementsa 600a-b of the page buffer 152 of FIG. 1 during the first BLSET phase and the second BLSET phase. The first arrangement 600a shown in FIG. 6A corresponds to the first BLSET phase and the second arrangement 600b shown in FIG. 6B corresponds to a portion of the first BLSET and the second BLSET phase. The first latch 243 may apply the inhibit voltage to the first bit line group via the first path 606. The second latch 245 may apply the inhibit voltage to the second bit line group via a second path 608 of transistors 612a-e.

As shown in FIG. 6A, during the first BLSET phase, the first path 606 is in a closed state (e.g., a propagating state) such that the first latch 243 can apply the inhibit voltage to the first bit line group. As shown in FIG. 6A, the transistors 610a, 610c, and 610e can be on and the transistors 610b and 610d can be off in the closed state of the first path 606 to permit the first latch 243 to apply the inhibit voltage to the first bit line group.

In addition, as shown in FIG. 6A, during the first BLSET phase, the second path 608 is in an open state (e.g., a not propagating state) such that the second latch 245 does not apply the inhibit voltage to the second bit line group. As shown in FIG. 6A, the transistors 612a, 612c, and 612d can be on and the transistors 612b and 612e can be off in the open state of the second path 608 to prevent the second latch 245 from applying the inhibit voltage to the second bit line group.

As shown in FIG. 6B, to make the first bit line group floating and also during the second BLSET phase, the first path 606 is in the open state such that the first latch 243 does not apply the inhibit voltage to the first bit line group (and the first bit line group is isolated). As shown in FIG. 6B, the transistors 610a, 610b, and 610e can be on and the transistors 610c and 610d can be off in the open state of the first path 606 to prevent the first latch 243 from applying the inhibit voltage to the first bit line group.

In addition, as shown in FIG. 6B, during the second BLSET phase, the second path 608 is in the closed state such that the second latch 245 can apply the inhibit voltage to the second bit line group. As shown in FIG. 6B, the transistors 612a, 612b, and 612d can be on and the transistors 612c and 612e can be off in the closed state of the second path 608 to permit the second latch 245 to apply the inhibit voltage to the second bit line group.

It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-6, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

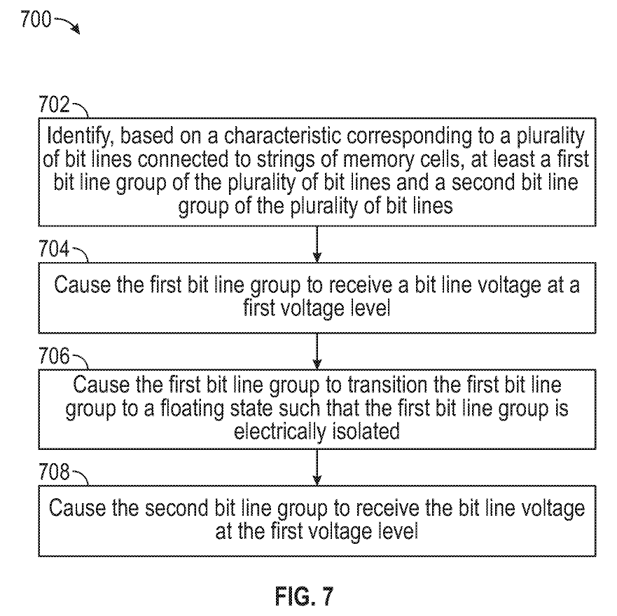

FIG. 7 illustrates a flowchart showing a method 700 that supports techniques for boosting bit line voltage in accordance with examples as disclosed herein. At least some of the blocks in method 700 can be performed by a controller (e.g., the local controller 135 of FIG. 1) during a program operation. At block 702, the controller identifies at least a first bit line group of a plurality of bit lines (e.g., bit lines 204) and a second bit line group of the plurality of bit lines (e.g., bit lines 204). The controller identifies the first bit line group, and the second bit line group based on a characteristic corresponding to the plurality of bit lines connected to strings of memory cells (e.g., NAND strings 206). In block 704, the controller causes the first bit line group to receive a bit line voltage at a first voltage level.

In block 706, the controller causes the first bit line group to transition to a floating state such that the first bit line group is electrically isolated. In block 708, the controller causes the second bit line group to receive the bit line voltage at the first voltage level. The first bit line group and the second bit line group can be capacitively coupled such that the voltage level of the first bit line group is boosted from the first voltage level to a second voltage level.

Method 700 may include additional blocks not shown in FIG. 7. For example, the characteristic corresponding to the plurality of bit lines may include threshold voltage distributions of select transistors coupled to the plurality of bit lines and the method 700 may include another block, in which the controller compares the threshold voltage distributions of the select transistors to a threshold value. In this example, a portion of the plurality of bit lines corresponding to select transistors that have threshold voltage distributions that are equal to or less than the threshold value are identified as the first bit line group and a portion of the plurality of bit lines corresponding to select transistors that have threshold voltage distributions that are greater than the threshold value are identified as the second bit line group.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
a plurality of bit lines connected to strings of memory cells;
a controller configured to perform, during a program operation of the strings of memory cells:
identifying, based on a characteristic corresponding to the plurality of bit lines, at least a first bit line group of the plurality of bit lines and a second bit line group of the plurality of bit lines:
causing the first bit line group to:
receive a bit line voltage at a first voltage level; and
transition to a floating state such that the first bit line group is electrically isolated; and
causing the second bit line group to receive the bit line voltage at the first voltage level, wherein the first bit line group and the second bit line group are capacitively coupled such that the voltage level of the first bit line group is boosted from the first voltage level to a second voltage level.

2. The memory device of claim 1, wherein the characteristic corresponding to the plurality of bit lines comprises threshold voltage distributions of select transistors coupled to the plurality of bit lines and the controller is further configured to perform:
obtaining the threshold voltage distributions of the select transistors,
wherein a portion of the plurality of bit lines corresponding to select transistors that have lower threshold voltage distributions are identified as the first bit line group and another portion of the plurality of bit lines corresponding to select transistors that have higher threshold voltage distributions are identified as the second bit line group.

3. The memory device of claim 1, wherein:
the controller is configured to cause the second bit line group to receive the bit line voltage to inhibit the corresponding strings of memory cells from being programmed; and
the first bit line group and the second bit line group are capacitively coupled such that the voltage level of the first bit line group is boosted from the first voltage level to the second voltage level to inhibit the strings of memory cells corresponding to the first bit line group from being programmed.

4. The memory device of claim 1, wherein the bit line voltage is equal to or less than two volts.

5. The memory device of claim 1, further comprising a page buffer electrically coupled to the plurality of bit lines, wherein the controller is configured to cause the page buffer to apply the bit line voltage at the first voltage level to the first bit line group and the second bit line group.

6. The memory device of claim 5, wherein:
the page buffer comprises a first latch corresponding the first bit line group and a second latch corresponding to the second bit line group;
the controller is configured to cause the first latch to apply the bit line voltage to the first bit line group via a first path of transistors during a first phase of the program operation; and
the controller is configured to cause the second latch to apply the bit line voltage to the second bit line group via a second path of transistors during a second phase of the program operation.

7. The memory device of claim 6, wherein:
the second path of transistors is in an open state when the first path of transistors is in a closed state; and
the first path of transistors is in the open state when the second path of transistors is in the closed state.

8. The memory device of claim 6, further comprising a sense amplifier.

9. The memory device of claim 1, further comprising select transistors coupled to the plurality of bit lines, wherein the causing the first bit line group to transition to the floating state comprises causing the select transistors corresponding to the first bit line group to turn off such that the first bit line group is electrically isolated.

10. The memory device of claim 1, wherein the controller is configured to perform, during the program operation of the strings of memory cells identifying, based on the characteristic corresponding to the plurality of bit lines, a third bit line group of the plurality of bit lines.

11. The memory device of claim 1, wherein:
the characteristic corresponding to the plurality of bit lines comprises threshold voltage distributions of select transistors coupled to the plurality of bit lines; and
the identifying at least the first bit line group of the plurality of bit lines and the second bit line group of the plurality of bit lines comprises comparing the threshold voltage distributions of the select transistors to a threshold value, wherein a portion of the plurality of bit lines corresponding to select transistors that have threshold voltage distributions that are equal to or less than the threshold value are identified as the first bit line group and a portion of the plurality of bit lines corresponding to select transistors that have threshold voltage distributions that are greater than the threshold value are identified as the second bit line group.

12. The memory device of claim 1, wherein the characteristic corresponding to the plurality of bit lines comprises an arrangement of the plurality of bit lines and the controller is configured to randomly identify the first bit line group of the plurality of bit lines and the second bit line group of the plurality of bit lines randomly based on the arrangement of the plurality of bit lines.

13. The memory device of claim 1, wherein the controller, in accordance with a plurality of program loops of the program operation being performed, is configured to identify at least the first bit line group of the plurality of bit lines and the second bit line group of the plurality of bit lines.

14. The memory device of claim 1 further comprising a plurality of drain select transistors and wherein the bit line voltage is less than a bias voltage being applied to gates of the plurality of drain select transistors.

15. A memory device comprising:
a plurality of bit lines connected to strings of memory cells;
a controller configured to perform, during a program operation of the strings of memory cells:
identifying, based on user input, at least a first bit line group of the plurality of bit lines and a second bit line group of the plurality of bit lines:
causing the first bit line group to:
receive a bit line voltage at a first voltage level; and
transition to a floating state such that the first bit line group is electrically isolated; and
causing the second bit line group to receive the bit line voltage at the first voltage level, wherein the first bit line group and the second bit line group are capacitively coupled such that the voltage level of the first bit line group is boosted from the first voltage level to a second voltage level.

16. A method comprising:
identifying, based on a characteristic corresponding to a plurality of bit lines connected to strings of memory cells, at least a first bit line group of the plurality of bit lines and a second bit line group of the plurality of bit lines;
causing the first bit line group to receive a bit line voltage at a first voltage level;
transitioning the first bit line group to a floating state such that the first bit line group is electrically isolated; and
causing the second bit line group to receive the bit line voltage at the first voltage level, wherein the first bit line group and the second bit line group are capacitively coupled such that the voltage level of the first bit line group is boosted from the first voltage level to a second voltage level.

17. The method of claim 16, wherein:
the characteristic corresponding to the plurality of bit lines comprises threshold voltage distributions of select transistors coupled to the plurality of bit lines; and
the method further comprises obtaining the threshold voltage distributions of the select transistors; and
a portion of the plurality of bit lines corresponding to select transistors that have lower threshold voltage distributions are identified as the first bit line group and another portion of the plurality of bit lines corresponding to select transistors that have higher threshold voltage distributions are identified as the second bit line group.

18. The method of claim 16, wherein:
the causing the second bit line group to receive the bit line voltage at the first voltage level causes the second bit line group to receive the bit line voltage to inhibit the corresponding strings of memory cells from being programmed; and
the second voltage level to inhibit the strings of memory cells corresponding to the first bit line group from being programmed.

19. The method of claim 16, wherein the causing the first bit line group to transition to the floating state comprises causing select transistors corresponding to the first bit line group to turn off such that the first bit line group is electrically isolated.

20. The method of claim 16, wherein:
the characteristic corresponding to the plurality of bit lines comprises threshold voltage distributions of select transistors coupled to the plurality of bit lines; and
the identifying at least the first bit line group of the plurality of bit lines and the second bit line group of the plurality of bit lines comprises comparing the threshold voltage distributions of the select transistors to a threshold value, wherein a portion of the plurality of bit lines corresponding to select transistors that have threshold voltage distributions that are equal to or less than the threshold value are identified as the first bit line group and a portion of the plurality of bit lines corresponding to select transistors that have threshold voltage distributions that are greater than the threshold value are identified as the second bit line group.
